(19) United States
(12) Patent Application Publication
(10) Pub. No.: US 2026/0088822 A1
(43) Pub. Date: Mar. 26, 2026

(54) LOW POWER MODE BIAS VOLTAGE OR CURRENT GENERATOR FOR CURRENT-STARVED INVERTERS OR OTHER DEVICES

(71) Applicant: QUALCOMM Incorporated, San Diego, CA (US)

(72) Inventors: Anand MERUVA, San Diego, CA (US); Prince MATHEW, San Diego, CA (US)

(21) Appl. No.: 18/895,873

(22) Filed: Sep. 25, 2024

(51) Int. Cl. H03L 7/081; G05F 3/26; H03K 3/037

(52) U.S. Cl. CPC H03L 7/0816; G05F 3/262; H03K 3/037

(57) ABSTRACT

An apparatus, including: a current generating circuit configured to generate a first current; a first current mirror including a first field effect transistor (FET) and a second FET, wherein the first FET is coupled to the current generating circuit such that the first current flows through the first FET; a first switching device coupled between a gate of the first FET and a gate of the second FET; and a capacitor coupled between a first voltage rail and the gate of the second FET.

### FIELD

This disclosure relates generally to bias voltage or current generators, and in particular, to a low power mode bias voltage or current generator for devices, such as current-starved inverters of a delayed locked loop (DLL).

### BACKGROUND

A delayed locked loop (DLL) may be configured to generate a set of clock signals with different phases. A clock signal is a substantially periodic signal. A DLL may be used in many applications, such as in serializer-deserializer (SERDES) applications. For example, a DLL may be used in a clock and data recovery (CDR) for generating a sampling clock signal whose sampling edge is substantially aligned with a center of an eye diagram (e.g., the most optimal sampling point) associated with data signal detection at a receiver of a SERDES communication link. As in many applications, power consumption of a DLL or components thereof is of particular interest.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an apparatus. The apparatus includes a current generating circuit configured to generate a first current; a first current mirror including a first field effect transistor (FET) and a second FET, wherein the first FET is coupled to the current generating circuit such that the first current flows through the first FET; a first switching device coupled between a gate of the first FET and a gate of the second FET; and a capacitor coupled between a first voltage rail and the gate of the second FET.

Another aspect of the disclosure relates to a method. The method includes generating a first current; mirroring the first current to generate a second current pursuant to a first mode of operation, wherein mirroring the first current comprises forming a first voltage at a terminal of a capacitor, wherein the second current is based on the first voltage; and ceasing the mirroring of the first current to generate the second current pursuant to a second mode of operation, wherein the capacitor substantially holds the first voltage to substantially maintain the second current.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1A illustrates a block diagram of an example serializer/deserializer (SERDES) communication link in accordance with an aspect of the disclosure.

FIG. 1B illustrates an eye diagram of an example differential data signal including an associated sampling clock signal in accordance with another aspect of the disclosure.

FIG. 2 illustrates a block diagram of an example delayed locked loop (DLL) in accordance with another aspect of the disclosure.

FIG. 3 illustrates a schematic diagram of an example current-starved inverter in accordance with another aspect of the disclosure.

FIG. 4 illustrates a schematic diagram of an example bias voltage generator for a current-starved inverter in accordance with another aspect of the disclosure.

FIG. 5 illustrates a block diagram of another example delayed locked loop (DLL) in accordance with another aspect of the disclosure.

FIG. 6 illustrates a schematic diagram of another example bias voltage generator for a current-starved inverter in accordance with another aspect of the disclosure.

FIG. 7 illustrates a timing diagram of an example operation of the bias voltage generator of FIG. 6 in accordance with another aspect of the disclosure.

FIG. 8 illustrates a block diagram of an example apparatus (e.g., a current generator) in accordance with another aspect of the disclosure.

FIG. 9 illustrates a flow diagram of an example method of generating a current in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

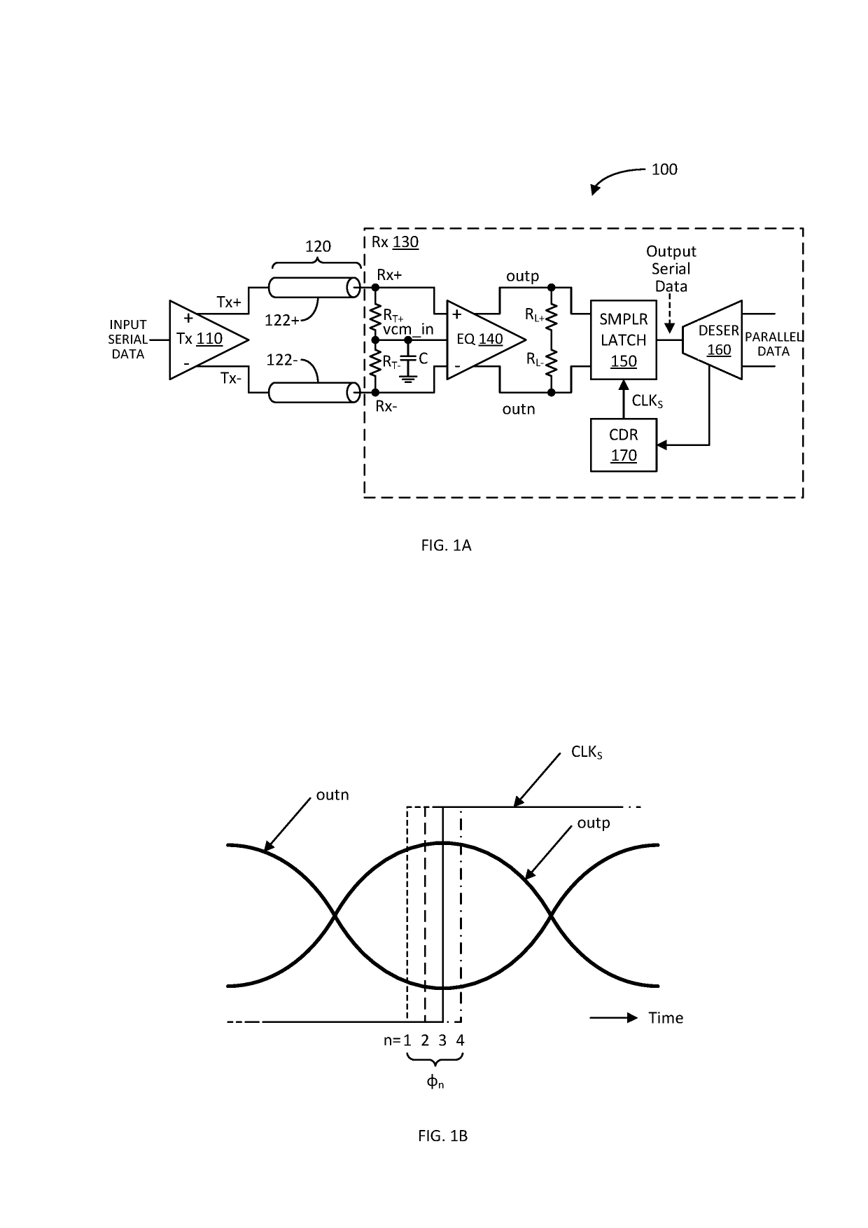

FIG. 1A illustrates a block diagram of an example serializer/deserializer (SERDES) communication link 100 in accordance with an aspect of the disclosure. In this example, the SERDES communication link 100 includes a single unidirectional data lane. However, it shall be understood that the SERDES communication link 100 may include a set of one or more unidirectional data lanes and/or a set of one or more bidirectional data lanes.

The SERDES communication link 100 includes a transmitter (Tx) 110 (e.g., transmit (Tx) driver) coupled to a receiver 130 via a data communication channel 120. The transmitter 110 may be configured to generate a transmit differential signal Tx+/Tx- based on an input serial data signal. The transmit differential signal Tx+/Tx- may be routed to the receiver 130 via differential transmission lines 122+/122- of the data communication channel 120, respectively. The data communication channel 120 typically has a low-pass frequency response or transfer function that reduces high frequency content of signals that propagate therethrough. Accordingly, at the receiver 130,the transmit differential signal Tx+/Tx-, which may be referred to as a received differential signal Rx+/Rx- from the perspective of the receiver 130, has its high frequency content reduced due to the data communication channel 120.

The receiver 130, in turn, includes a pair of termination resistors RT+ and RT- coupled between the differential transmission lines 122+ and 122- and an input common mode node. An input common mode voltage vcm_in may be generated at the input common mode node based on the received differential signal Rx+/Rx-. The termination resistors RT+ and RT- reduce signal reflections at the differential input of the receiver 130. The receiver 130 further includes a capacitor C coupled between the input common mode node and a lower voltage rail (e.g., ground) to filter the input common mode voltage vcm_in.

The receiver 130 includes an equalizer (e.g., a continuous time linear equalizer (CTLE)) 140 including a differential input +/- configured to receive the received differential signal Rx+/Rx-, respectively. The CTLE 140 is configured to equalize or compensate the received differential signal Rx+/Rx- for high frequency losses incurred while propagating via the data communication channel 120 to generate an output differential signal outp/outn across a pair of load resistors RL+/RL-, respectively. The CTLE 140 may use the input common mode voltage vcm_in to perform its equalization operation.

The receiver 130 further includes a sampler/latch 150 configured to sample the output differential signal outp/outn based on a sampling clock signal CLK_{S} to generate an output serial data. Additionally, the receiver 130 includes a deserializer 160 configured to deserialize the output serial data to generate a set of parallel data. Further, the receiver 130 includes a clock and data recovery (CDR) 170 configured to generate the sampling clock signal CLK_{S} based on a feedback signal from the deserializer 160. The CDR 170 may include a delayed locked loop (DLL) configured to generate a set of clock signals with different phases, and a clock phase selector configured to select one of the set of clock signals as the sampling clock signal CLK_{S} based on the feedback signal. The selected clock signal may include a sampling edge substantially aligned with the center of an eye associated with the differential data signal outp/outn for optimal data detection purposes.

FIG. 1B illustrates an eye diagram of the example differential data signal outp/outn and example sampling clock signal CLK_{S} of the SERDES communication link 100 in accordance with another aspect of the disclosure. The horizontal axis of the eye signal diagram represents time. The vertical axis of the eye signal diagram represents amplitude of the differential data signal outp/outn and sampling clock signal CLK_{S}.

As the eye diagram illustrates, the positive component outp of the differential data signal outp/outn exhibits a positive peak at phase (clock sampling edge) “3” or ϕ₃ (indicated as a solid line) of the sampling clock signal CLK_{S}. Similarly, the negative component outn of the differential data signal outp/outn exhibits a negative peak at ϕ₃ of the sampling clock signal CLK_{S.} At phase 3, the amplitude difference between the positive component outp and the negative component outn of the differential data signal outp/outn is maximum (e.g., which coincides with the center of the eye diagram). Accordingly, the phase of the sampling clock signal CLK_{S} being at phase 3 maximizes the successful detection/sampling of the data carried by the differential data signal. Other phases of the sampling clock signal CLK_{S}, such as 1-2 and 4 (indicated by various dashed-type lines), are not situated at the maximum amplitude difference between positive component outp and the negative component outn of the differential data signal outp/outn.

Accordingly, if the current phase of the sampling clock signal CLK_{S} is other than at phase ϕ₃ (e.g., at ϕ₁), the amplitude difference between the positive component outp and the negative component outn of the differential data signal outp/outn is not maximum. This information may be ascertained based on feedback information from the deserializer 160 concerning the detected data (e.g., a bit error rate (BER) associated with training data). In response, the phase selector of the CDR 170 selects the clock signal from the DLL with the phase ϕ₃ to maximize a difference between the positive component outp and the negative component outn of the differential data signal outp/outn.

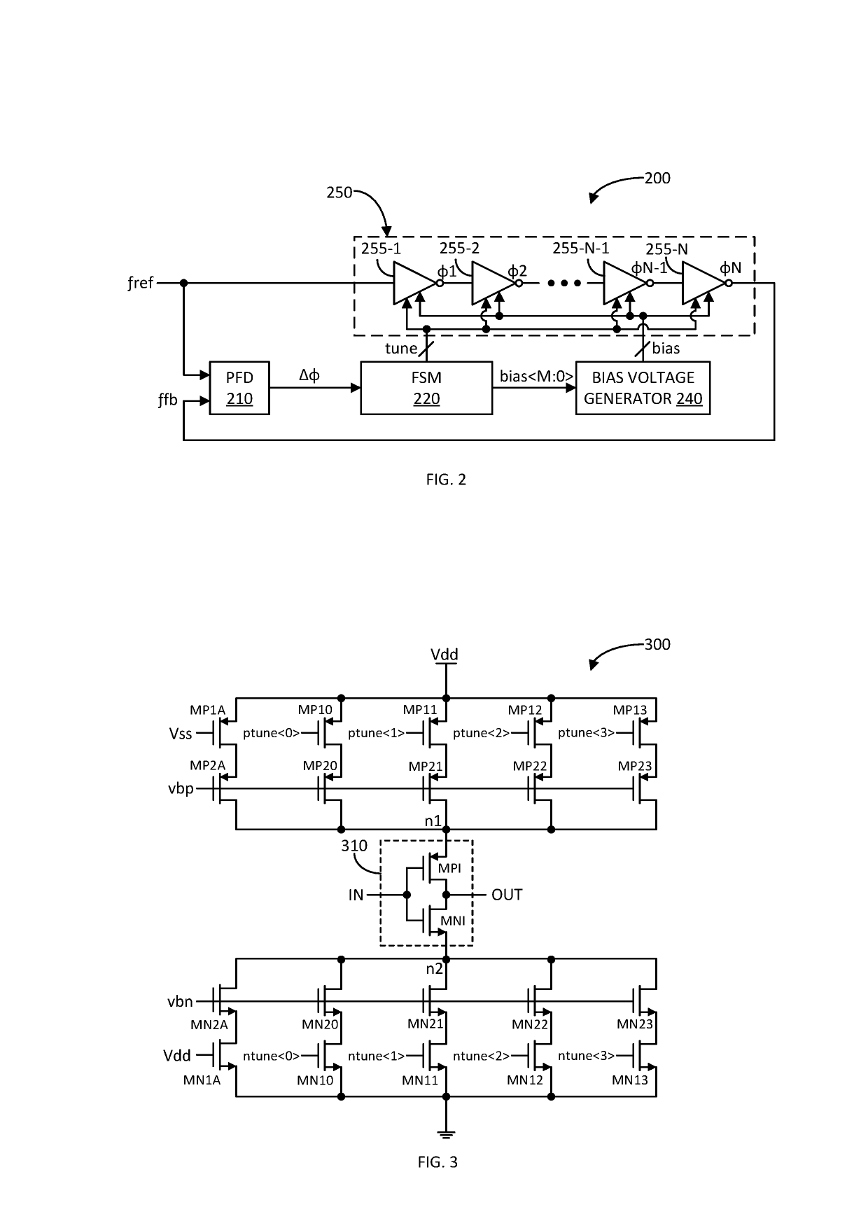

FIG. 2 illustrates a block diagram of an example delayed locked loop (DLL) 200 in accordance with another aspect of the disclosure. The DLL 200 includes a voltage-controlled delay line (VCDL) 250 including a set of cascaded current-starved inverters 255-1 to 255-N, where N is an integer of two (2) or more. The DLL 200 further includes a phase frequency detector (PFD) 210, a finite state machine (FSM) 220, and a bias voltage generator 240.

The PFD 210 is configured to phase-frequency compare a reference clock signal /ref with a feedback clock signal ƒfb to generate a phase error signal Δϕ based on the comparison. The FSM 220 is configured to generate a tune control signal and a bias control signal bias<M:0> for the VCDL 250 based on the phase error signal Δϕ. The bias voltage generator 240 is configured to generate a bias signal for the VCDL 250 based on the bias control signal bias<M:0>. The delay of each of the cascaded current-starved inverters 255-1 to 255-N are adjusted based on the tune and bias signals.

The VCDL 250 includes an input configured to receive the reference clock signal ƒref The cascaded current-starved inverters 255-1 to 255-N of the VCDL 250 are configured to cumulatively delay the reference clock signal ƒref to generate the feedback clock signal ƒfb. Based on the phase error signal Δϕ, and more generally, the loop operation, the FSM 220 and the bias voltage generator 240 are configured to generate the tune and bias signal to cause the phase/frequency of the feedback clock signal ƒfb to be substantially the same (or locked with) the phase/frequency of the reference clock signal ƒref (e.g., Δϕ=0). When the DLL 200 is locked, the VCDL 250 generates a set of clock signals with substantially equally-spaced phases ϕ₁ to ϕ_{1N} (e.g., 360 degrees/N), respectively.

In CDR application, a phase selector may be coupled to the VCDL 250 for selecting one of the set of clock signals with substantially equally-spaced phases ϕ₁ to ϕ_{1N} for the sampling clock signal CLK_{S.} It shall be understood that the DLL 200 may be configured in different manners for CDR application or other applications. Once the VCDL 250 is calibrated per the phase/frequency locking operation of the DLL 200, the loop operation of the DLL 200 may be temporality disabled, and the FSM 220 and bias voltage generator 240 may maintain the tune and bias signals substantially constant until a subsequent phase/frequency locking operation (which may be performed at regular intervals) produces different tune and/or bias signals.

FIG. 3 illustrates a schematic diagram of an example current-starved inverter 300 in accordance with another aspect of the disclosure. The current-starved inverter 300 may be an example implementation of any one of the current-starved inverters 255-1 to 255-N of the VCDL 250 of DLL 200.

The current-starved inverter 300 includes a first p-channel field effect transistor (PFET) MP1A coupled in series with a second PFET MP2A between an upper voltage rail Vdd and a first internal node n1. More specifically, the first PFET MP1A includes a source coupled to the upper voltage rail Vdd, a gate configured to receive a voltage potential Vss at a lower voltage rail (e.g., ground, where Vss=0 Volt (V)), and a drain coupled to a source of the second PFET MP2A. The second PFET MP2A includes a gate configured to receive a positive-side (p-side) bias voltage vbp, and a drain coupled to the first internal node n1.

The current-starved inverter 300 further includes a first set of PFETs MP10 to MP13 coupled in series with a second set of PFETs MP20 to MP23 between the upper voltage rail Vdd and the internal node n1, respectively. That is, the first set of PFETs MP10 to MP13 include sources coupled to the upper voltage rail Vdd, gates configured to receive p-side coarse delay tuning control signals ptune<0> to ptune<3> and drains coupled to sources of the second set of PFETs MP20 to MP23 respectively. The second set of PFETs MP20 to MP23 include gates coupled together (and to the gate of PFET MP2A) and configured to receive the p-side bias voltage vbp, and drains coupled to the first internal node n1.

The current-starved inverter 300 includes a second n-channel field effect transistor (NFET) MN2A coupled in series with a first NFET MP1A between a second internal node n2 and the lower voltage rail (e.g., ground). More specifically, the second NFET MN2A includes a drain coupled to the second internal node n2, a gate configured to receive a negative-side (n-side) bias voltage vbn, and a source coupled to a drain of the first NFET MN1A. The first NFET MN1A includes a gate configured to receive a voltage potential at the upper voltage rail Vdd (e.g., the voltage potential also referred to herein as Vdd), and a source coupled to the lower voltage rail.

The current-starved inverter 300 further includes a second set of NFETs MN20 to MN23 coupled in series with a first set of NFETs MN10 to MN13 between the second internal node n2 and the lower voltage rail. That is the second set of NFETs MN20 to MN23 include drains coupled to the second internal node n2, gates coupled together (and to the gate of NFET MN2A) and configured to receive the n-side bias voltage vbn, and sources coupled to drains of the first set of NFETs MN10 to MN13 respectively. The first set of NFETs MN10 to MN13 include gates configured to receive n-side coarse delay tuning control signals ntune<0> to ntune<3>, and sources coupled to the lower voltage rail, respectively.

The current-starved inverter 300 includes an inverter core 310 including a PFET MPI coupled in series with an NFET MNI between the first internal node n1 and the second internal node n2. That is the PFET MPI includes a source coupled to the first internal node n1. The NFET MNI includes a source coupled to the second internal node n2. The PFET MP1 and NFET MNI include respective gates coupled together and serving as an input IN of the current-starved inverter 300. The PFET MP1 and NFET MNI include respective drains coupled together and serving as an output (OUT) of the current-starved inverter 300.

With further reference to the DLL 200 as mentioned the current-starved inverter 300 may be an example of each of the current-starved inverters 255-1 to 255-N. The tune control signal generated by the FSM 220 may include the p-side coarse tune control signal ptune<3:0> and the n-side coarse tune control signal ntune<3:0>. Also the bias signal generated by the bias voltage generator 240 may include the p-side bias voltage vbp and the n-side bias voltage vbn. The inputs and outputs of each of the current-starved inverters 255-1 to 255-N correspond to the input (IN) and output (OUT) of the inverter core 310, respectively.

In general the delay imparted to an input clock signal provided to the input (IN) to generate an output signal at the output (OUT) is inversely related to the current flowing through the inverter core 310. The first PFET MP1A operates as an always-on switching device. The first set of PFETs MP10 to MP13 operate as programmable switching devices (e.g., ON/OFF state) based on the p-side coarse tune control signals ptune<0> to ptune<3>, respectively. The second PFET MP2A and the second set of PFETs MP20 to MP23 operate as current sources. The second PFET MP2A and the second set of PFETs MP20 to MP23 may be sized to provide binary-weighted currents, equally-weighted currents, or other weighted-currents.

A switching device as defined herein, includes a pair of terminals which may be electrically coupled together (e.g., in an ON or closed state) or electrically decoupled from each other (e.g., in an OFF or open state) based on a control signal. A switching device may be implemented as a FET, a pass gate a transmission gate, or other one or more devices.

Similarly the first NFET MN1A operates as an always-on switching device. The first set of NFETs MN10 to MN13 operate as programmable switching devices (e.g., ON/OFF state) based on the n-side coarse tune control signals ntune<0> to ntune<3>, respectively. The second NFET MN2A and the second set of NFETs MN20 to MN23 operate as current sources (e.g., sometimes referred to as current sinks). The second NFET MN2A and the second set of NFETs MN20 to MN23 may be sized to provide binary-weighted currents equally-weighted or other weighted-currents. The second NFET MN2A and the second set of NFETs MN20 to MN23 may be sized similar to the second PFET MP2A and the second set of PFETs MP20 to MP23 to provide substantially the same currents, respectively.

In operation the always-on switching devices MP1A and MN1A enable the current sources PFET MP2A and NFET MN2A to provide a minimum current to the inverter core 310. This results in a maximum delay imparted to an input clock signal to generate an output clock signal. The first set of programmable switching devices MP10 to MP13 and the first set of programmable switching devices MN10 to MN13 may be controlled via the p-side coarse tune control signals ptune<0> to ptune<3> (e.g., ptune<>=Vss/Vdd to turn on/off the corresponding PFET) and n-side coarse tune control signals ntune<0> to ntune<3> (e.g., ntune<>=Vdd/Vss to turn onoff the corresponding NFET) to selectively provide progressively increasing current to the inverter core 310, respectively. This results in selectively and progressively reducing the delay imparted to the input clock signal from the always-on maximum delay based on the coarse tune control signals ptune<3:0>/ntune<3:0>.

As indicated the tune control signals ptune<3:0>/ntune<3:0> provide a coarse control of the delay imparted to an input clock signal by the current-starved inverter 300. The bias voltages vbp and vbn provide a fine control of the delay imparted to an input clock signal by the current-starved inverter 300. For example, if the p-side bias voltage vbp is reduced and the n-side bias voltage vbn is increased, the corresponding always-on and selected current sources MP2A/MN2A and MP20-MP23/MN20-MN23 provide higher current to the inverter core 310 to decrease the delay imparted to an input clock signal by the current-starved inverter 300. Conversely, if the p-side bias voltage vbp is increased and the n-side bias voltage vbn is reduced, the corresponding always-on and selected current sources MP2A/MN2A and MP20-MP23/MN20-MN23 provide lower current to the inverter core 310 to increase the delay imparted to an input clock signal by the current-starved inverter 300.

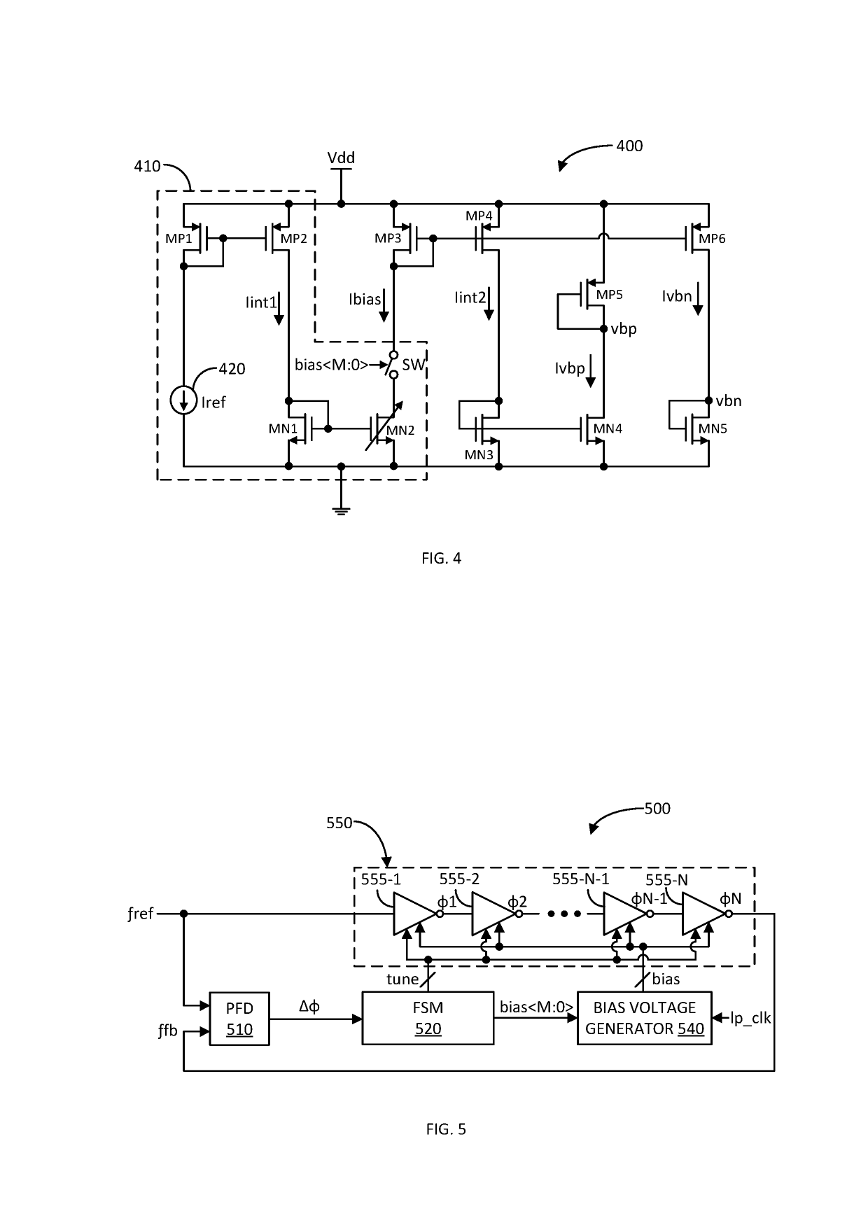

FIG. 4 illustrates a schematic diagram of an example bias voltage generator 400 for a current-starved inverter in accordance with another aspect of the disclosure. The bias voltage generator 400 may be an example implementation of the bias voltage generator 240 for generating the p-side bias voltage vbp and the n-side bias voltage vbn.

The bias voltage generator 400 includes a current generating circuit 410 including a first PFET MP1 coupled in series with a reference current source 420 between an upper voltage rail Vdd and a lower voltage rail (e.g., ground). That is, the first PFET MP1 includes a source coupled to the upper voltage rail Vdd, and a gate and a drain coupled together. The reference current source 420 is coupled between the gate/drain of the first PFET MP1 and the lower voltage rail.

The current generating circuit 410 further includes a second PFET MP2 coupled in series with a first NFET MN1 between the upper voltage rail Vdd and the lower voltage rail. That is, the second PFET MP2 includes a source coupled to the upper voltage rail Vdd, a gate coupled to the gate/drain of the first PFET MP1, and a drain coupled to a drain/gate of the first NFET MN1. As indicated, the first NFET MN1 includes gate and drain coupled together, and a source coupled to the lower voltage rail.

The current generating circuit 410 includes a set of M switching devices SW and a set of M NFETs MN2 coupled in series between a third PFET MP3 and the lower voltage rail, where M is an integer of two (2) or more (e.g., M=6). The set of M switching devices SW are coupled between a drain of the third PFET MP3 and drains of the set of M NFETs MN2, respectively. The set of M NFETs MN2 include gates coupled to the gate of the first NFET MN1, and sources coupled to the lower voltage rail. The on/off state of the set of M switching devices SW are controlled by the bias control signal (e.g., a thermometer code) bias<M:0>. The set of M NFETs MN2 may have binary-weighted sizes equally-weighted sizes, or other weighted sizes, for current mirror gain purposes, as discussed further herein.

As indicated the bias voltage generator 400 includes the third PFET MP3 coupled in series with the set of M switching devices SW and the set of M NFETs MN2 between the upper voltage rail Vdd and the lower voltage rail, respectively. That is, the third PFET MP3 includes a source coupled to the upper voltage rail Vdd, and gate and drain coupled together. The bias voltage generator 400 further includes a fourth PFET MP4 coupled in series with a third NFET MN3 between the upper voltage rail Vdd and the lower voltage rail. That is, the fourth PFET MP4 includes a source coupled to the upper voltage rail Vdd, a gate coupled to the gate/drain of the third PFET MP3, and a drain coupled to a drain/gate of the third NFET MN3 The third NFET MN3 includes gate and drain coupled together, and a source coupled to the lower voltage rail.

The bias voltage generator 400 includes a diode-connected fifth PFET MP5 coupled in series with a fourth NFET MN4 between the upper voltage rail and the lower voltage rail. That is, the diode-connected PFET MP5 includes a source coupled to the upper voltage rail Vdd, and a gate and a drain coupled together. The fourth MN4 includes a drain coupled to the gate/drain of the diode-connected PFET MP5, a gate coupled to the gate/drain of the third NFET MN3, and a source coupled to the lower voltage rail.

The bias voltage generator 400 further includes a sixth PFET MP6 coupled in series with a diode-connected (fifth) NFET MN5 between the upper voltage rail Vdd and the lower voltage rail. That is, the sixth PFET MP6 includes a source coupled to the upper voltage rail Vdd, a gate coupled to the gates of the PFETs MP3 and MP4, and a drain coupled to drain/gate of the diode-connected NFET MN5. The diode-connected NFET MN5 further includes a source coupled to the lower voltage rail.

In operation with regard to the current generating circuit 410, the reference current source 420, which may be implemented as a bandgap current source, is configured to generate a reference current Iref (e.g., a bandgap current). The first PFET MP1 and the second PFET MP2 form a current mirror to mirror the reference current Iref to generate a first intermediate current Iint1 flowing through the second PFET MP2 and the first NFET MN1.

Similarly the first NFET MN1 and selected one or more of the set of M NFETs MN2 are coupled together to form a current mirror to mirror the first intermediate current Iint1 to generate a bias current Ibias flowing through the third PFET MP3. The current gain Ibias/Iint1 depends on how many of the set of M NFETs MN2 are selected and their corresponding weighted-sizes. The set of M NFETs MN2 are selected by the corresponding set of switching devices SW being turned on by the bias control signal bias<M:0>. For example, assuming M=6, if the control signal bias<M=0> is set to 000001, a first one of the set of switching devices SW is turned on (the rest are turned off), and the corresponding NFET MN2 has a binary weighted-size of 2°=1 with respect to the size of the first NFET MN1 then the current gain Ibias/Iint1 is one (1). Considering another example, if the control signal bias<M:0> is 000110, the second and third ones of the set of switching devices SW are turned on (the rest are turned off), and the corresponding NFETs MN2 have respective binary weighted-sizes of 2¹ and 2² for a cumulative weight of six (6) with respect to the size of the first NFET MN1, then the current gain Ibias/Int1 is six (6).

Continuing with the operation of the bias voltage generator 400, the third PFET MP3 and the fourth PFET MP4 are coupled together to form a current mirror to mirror the bias current Ibias to generate a second intermediate current Iint2 flowing through the fourth PFET MP4 and the third NFET MN3. The third NFET MN3 and the fourth NFET MN4 are coupled together to form a current mirror to mirror the second intermediate current Iint2 to generate a p-side bias current Ivbp flowing through the diode-connected PFET MP5 and the fourth NFET MN4. The diode-connected PFET MP5 is configured to generate the p-side bias voltage vbp (for the current-starved inverters 255-1 to 255-N of the VCDL 250 or the current-starved inverter 300) at its gate/drain based on the p-side bias current Ivbp.

Similarly the third PFET MP3 and the sixth PFET MP6 are coupled together to form a current mirror to mirror the bias current Ibias to generate a n-side bias current Ivbn flowing through the sixth PFET MP6 and the diode-connected NFET MN5. The diode-connected NFET MN5 is configured to generate the n-side bias voltage vbn (for the current-starved inverters 255-1 to 255-N of the VCDL 250 or the current-starved inverter 300) at its gate/drain based on the n-side bias current Ivbn.

Further in operation with regard to the DLL 200, the bias voltage generator 240 may adjust the p-side bias voltage vbp and n-side bias voltage vbn via the control signal bias<M:0> generated by the FSM 220. For example, if the FSM 220 increases the temperature code of the control signal bias<M:0>, the current gain Ibias/Iint1 may correspondingly increase. Through current mirror operations, the increase in the bias current Ibias results in a corresponding increase in the p-side bias current Ivbp and the n-side bias current Ivbn. The increase in the p-side bias current Ivbp produces a decrease in the p-side bias voltage vbp. The increase in the n-side bias current Ivbn produces an increase in the n-side bias voltage vbn. And, as discussed, a decrease in the p-side bias voltage vbp and an increase in the n-side bias voltage vbn increases the current through the inverter core 310 of the current-starved inverter 300, which decreases the delay imparted to an input clock signal by the current-starved inverter 300 or each of the current-starved inverters 255-1 to 255-N of the VCDL 250.

Similarly, if the FSM 220 decreases the temperature code of the control signal bias<M:0> the current gain Ibias/Iint1 may correspondingly decrease Through current mirror operations the decrease in the bias current Ibias results in a corresponding decrease in the p-side bias current Ivbp and the n-side bias current Ivbn. The decrease in the p-side bias current Ivbp produces an increase in the p-side bias voltage vbp. The decrease in the n-side bias current Ivbn produces a decrease in the n-side bias voltage vbn. And, as discussed an increase in the p-side bias voltage vbp and a decrease in the n-side bias voltage vbn decreases the current through the inverter core 310 of the current-starved inverter 300 which increases the delay imparted on an input clock signal by the current-starved inverter 300 or each of the current-starved inverters 255-1 to 255-N of the VCDL 250.

A drawback of the bias voltage generator 400 is that the currents Iref, Int1, Ibias, Iint2, Ivbp, and Ivbn need to be maintained to generate the bias voltages vbp and vbn. This results in the bias voltage generator 400 consuming significant power. Thus, there is a need for a bias voltage generator that is able to substantially maintain the bias voltages vbp and vbn for the current-starved inverters 255-1 to 255-N of the VCDL 250 or current-starved inverter 300 while not consuming the power needed to maintain the currents Iref, Int1, and Ibias.

FIG. 5 illustrates a block diagram of another example delayed locked loop (DLL) 500 in accordance with another aspect of the disclosure. The DLL 500 may be similar to DLL 200 including many of the same/similar elements as indicated by the same reference numbers with the exception that they have a “5” as their most significant digital in DLL 500. The DLL 500 differs from DLL 200 in that it is configured to receive a clock signal lp_clk for operating the bias voltage generator 540 between a normal mode of operation and a low power mode (LPM) of operation. The low power mode (LPM) allows the bias voltage (e.g., vbp and vbn) to be generated for the set of current-starved inverters 555-1 to 555-N of the voltage controlled delay line (VCDL) 550 or current-starved inverter 300 while ceasing the generation of the reference current Iref, first intermediate current Iint1, and bias current Ibias to save power, as discussed in more detail further herein.

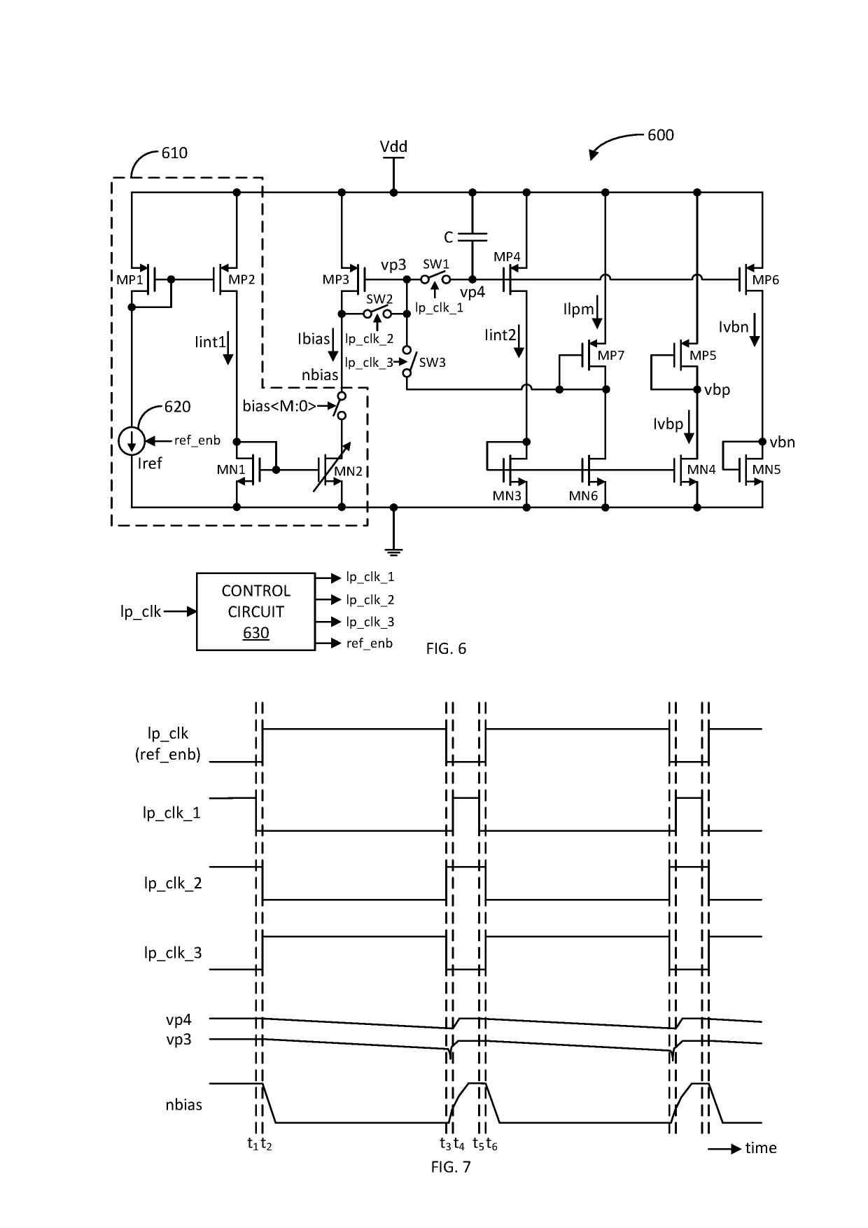

FIG. 6 illustrates a schematic diagram of another example bias voltage generator 600 for a current-starved inverter in accordance with another aspect of the disclosure. The bias voltage generator 600 may be an example implementation of bias voltage generator 540 of DLL 500. The bias voltage generator 600 includes many of the same/similar elements as bias voltage generator 400 as indicated by the same reference identifiers.

The bias voltage generator 600 differs from bias voltage generator 400 in that it includes additional elements to configure the bias voltage generator 600 in a low power mode (LPM). In this regard, the bias voltage generator 600 includes a control circuit 630 configured to receive the clock signal lp_clk and generate a set of clock signals lp_clk1, lp_clk2, and lp_clk3, and a reference current disable signal ref_enb based on the clock signal lp_clk. As indicated, the reference current source 620 is configured to receive and respond to the reference current disable signal ref_enb.

The bias voltage generator 600 further includes a first switching device SW1 (e.g., may be implemented as a field effect transistor (FET)) coupled between the gate of the third PFET MP3 and the gate of the fourth PFET MP4. The bias voltage generator 600 also includes a second switching device SW2 (e.g., a FET) coupled between the drain and the gate of the third PFET MP3. Additionally, the bias voltage generator 600 includes a capacitor C coupled between the upper voltage rail Vdd and the gate of the fourth PFET MP4.

Additionally the bias voltage generator 600 includes a diode-connected (seventh) PFET MP7 coupled in series with a sixth NFET MN6 between the upper voltage rail Vdd and the lower voltage rail (e.g., ground). That is, the diode-connected PFET MP7 includes a source coupled to the upper voltage rail Vdd and gate and drain coupled together and to a drain of the sixth NFET MN6. The sixth NFET MN6 includes a gate coupled to the gates of the third and fourth NFETs MN3 and MN4, and a source coupled to the lower voltage rail. Additionally, the bias voltage generator 600 includes a third switching device SW3 (e.g., FET) coupled between the gate/drain of the diode-connected PFET MP7 and the gate of the third PFET MP3 The on/off states of the switching devices SW1, SW2, and SW3 are controlled by clock signals lp_clk_1, lp_clk_2, and lp_clk_3, respectively.

From a high-level the bias voltage generator 600 operates as follows: During normal mode of operation (e.g., not low power mode (LPM)): the control circuit 630 deasserts the reference current disable signal ref_enb turns on the first and second switching devices SW1 and SW2, and turns off the third switching device SW3. In this configuration the bias voltage generator 600 operates similar to bias voltage generator 400 previously discussed. That is, the reference current generator 620 generates the reference current Iref, the first set of current mirrors MP1/MP2 and MN1/MN2 are configured to generate the bias current Ibias based on the reference current Iref, as previously discussed. Also, as previously discussed the second set of current mirrors MP3/MP4/MN3/MN4 and MP4/MP6 are configured to generate the p-side bias current Ivbp and the n-side bias current Ivbn based on the bias current Ibias respectively. The p-side bias current Ivbp and the n-side bias current Ivbn are used to generate the p-side bias voltage vbp and vbn, respectively. A difference between the normal mode of operation of the bias voltage generator 600 and the operation of the bias voltage generator 400 is that the capacitor C may be discharged based on the voltage vp4 at the gate of the fourth PFET MP4 as the capacitor C is not present in bias voltage generator 400.

In lower power mode (LPM) the control circuit 630 asserts the reference current disable signal ref_enb turns off the first and second switching devices SW1 and SW2, and turns on the third switching device SW3. In this configuration, the reference current source 620 ceases to generate the reference current Iref, the first intermediate current Iint1, and the bias current Ibias to reduce the power consumed by the bias voltage generator 600. The capacitor C substantially holds the voltage vp4 at the gate of the fourth PFET MP4 (e.g., generated during the normal mode of operation) so that the second intermediate current Iint2, the p-side bias current Ivbp and the n-side bias current Ivbn are maintained generated so that the p-side bias voltage vbp and n-side bias voltage vbn are likewise maintained generated.

The voltage vp4 (at the gate of the fourth PFET MP4) is applied to the right terminal of the first switching device SW1. The third switching device SW3 is turned on to provide a voltage vp3 to the left terminal of the first switching device SW1, and the second switching device SW2 is turned off so that the voltage vp3 does not dissipate through the current generating circuit 610. The voltage vp3 is generated at the gate/drain of the diode-connected PFET MP7 based on a low power mode current Ilpm. Accordingly the diode-connected PFET MP7 operates as a voltage generating circuit to generate the voltage vp3.

The voltage vp3 being substantially equal to the voltage vp4 at the gate of the fourth PFET MP4 (e.g., both being a gate-to-source voltage below the Vdd), produces substantially no voltage difference across the first switching device SW1 to prevent leakage current through the first switching device SW1 that may discharge from the capacitor C. This is done to prevent a lowering of the voltage vp4 at the gate of the fourth PFET MP4, which would otherwise, produce errors in the current mirroring for generating the currents Iint2, Ivbp, and Ivbn; and consequently, errors in the bias voltages vbp and vbn. This may have the negative effects of producing errors in the delay effectuated by the current-starved inverters 555-1 to 555-N of the VCDL 550 of the DLL 500 or the current-starved inverter 300. The aforementioned normal mode and low power mode (LPM) of operations are discussed in more detail with reference to the following timing diagram.

FIG. 7 illustrates a timing diagram of an example operation of the bias voltage generator 600 in accordance with another aspect of the disclosure. The horizontal axis of the timing diagram represents time. The vertical axis of the timing diagram from top to bottom represents the logic states of the clock signals lp_clk (also ref_enb), lp_clk_1, lp_clk_2, and lp_clk_3 and the voltages vp4, vp3, and nbias (at the drain of the third PFET MP3).

Prior to time t₁, which is slightly before a rising edge of the input clock signal lp_clk, the control circuit 630 generates the first and second clock signals lp_clk_1 and lp_clk_2 at high (asserted) logic states, the third clock signal lp_clk_3 at a low (deasserted) logic state, and the reference current disable signal ref_enb at a low (deasserted) logic state. In this configuration, the first and second switching devices SW1 and SW2 are turned on, the third switching device SW3 is turned off, and the reference current source 620 is turned on. In this configuration, the bias voltage generator 600 is operating in normal mode, as previously discussed.

During time interval t₂-t₃, the control circuit 630 generates the first and second clock signals lp_clk_1 and lp_clk_2 at low (deasserted) logic states, the third clock signal lp_clk_3 at a high (asserted) logic state, and the reference current disable signal ref_enb at a high (asserted) logic state. In this configuration, the first and second switching devices SW1 and SW2 are turned off, the third switching device SW3 is turned on, and the reference current source 620 is turned off. In this configuration, the bias voltage generator 600 is operating in low power mode (LPM), as previously discussed.

To preserve the voltage vp4 at the gate of the fourth PFET MP4, the first switching device SW1 is turned off first when transitioning from normal mode to low power mode (LPM). That is, at time t₁, the control circuit 630 deasserts the clock signal lp_clk_1 to turn off the first switching device SW1. This may be referred to as a first transition mode of operation during time interval t₁-t₂. The turning off of the first switching device SW1 isolates the gate of the fourth PFET MP4 from the current generating circuit 610 so that the voltage vp4 is not disturbed by the subsequent placing of the current generating circuit 610 in low power mode (LPM) at time t₂.

Similarly, the low power mode (LPM) ends at time t₃ with the second switching device SW2 being turned on, the third switching device SW3 being turned off, and the reference current disable signal ref_enb being deasserted. Then, at time t₄, the control circuit 630 asserts the clock signal lp_clk_1 to turn on the first switching device SW1 to configure the bias voltage generator 600 in normal mode. The interval between the end of low power mode (LPM) at time t₃ and the start of the normal mode at time t₄ may be referred to as a second transition mode of operation. Accordingly, during the transition from low power mode (LPM) to normal mode during time interval t₃-t₄, the turned-off first switching device SW1 isolates the gate of the fourth PFET MP4 from the current generating circuit 610 so that the voltage vp4 is not disturbed by the enabling of the current generating circuit 610 at time t₃.

The timing diagram also shows the effects on the voltage vp4 at the gate of the fourth PFET MP4. During normal operation prior to time t₁, the voltage vp4 at the gate of the fourth PFET MP4 is at a level driven by the enabled current generating circuit 610. During the first transition mode during interval t₁-t₂, as the first switching device SW1 is turned off and the current generating circuit 610 is no longer coupled to the gate of the fourth PFET MP4, the voltage vp4 begins to slowly decrease as it is substantially held by the capacitor C to maintain the generation of the currents Iint2, Ivbp, Ivbn, as well as the bias voltages vbp and vbn. The voltage vp4 continues to slowly decrease until it is corrected to its normal level when the first switching device SW1 is turned on at substantially time t₄ pursuant to normal mode of operation. The frequency of the input clock signal lp_clk may be selected to limit the decrease in the voltage vp4 during the low power mode (LPM) of operation so as not to significantly disturb the bias voltages vbp and vbn; and ultimately, the delays imparted by the current-starved inverters 555-1 to 555-N or current-starved inverter 300.

The voltage vp3 at the gate of the third PFET MP3 also decreases at substantially the same rate as the voltage vp4 at the gate of the fourth PFET MP4. This is because the voltage vp3, which is generated by the diode-connected PFET MP7, is based on the voltage vp4 via the low power mode current Ilpm generated by the current mirror MN3/MN6 based on the second intermediate current Iint2, which, in turn, is based on the voltage vp4 at the gate of the fourth PFET MP4. However, it may exhibit a glitch when the current generating circuit 610 is enabled at substantially time t₃ as it is not isolated from the current generating circuit 610.

The voltage nbias at the drain of the third PFET MP3 rises and falls in accordance with the enabling and disabling of the current generating circuit 610, respectively. For example, when the low power mode (LPM) is enabled at time t₂, the voltage nbias decreases from its normal operating mode level to substantially zero (0) Volt, and when the low power mode (LPM) is disabled at time t₃, the voltage nbias increases to its normal operating mode level. Due to the capacitor C, the rate at which the voltage nbias increases is less than the rate at which the voltage nbias decreases.

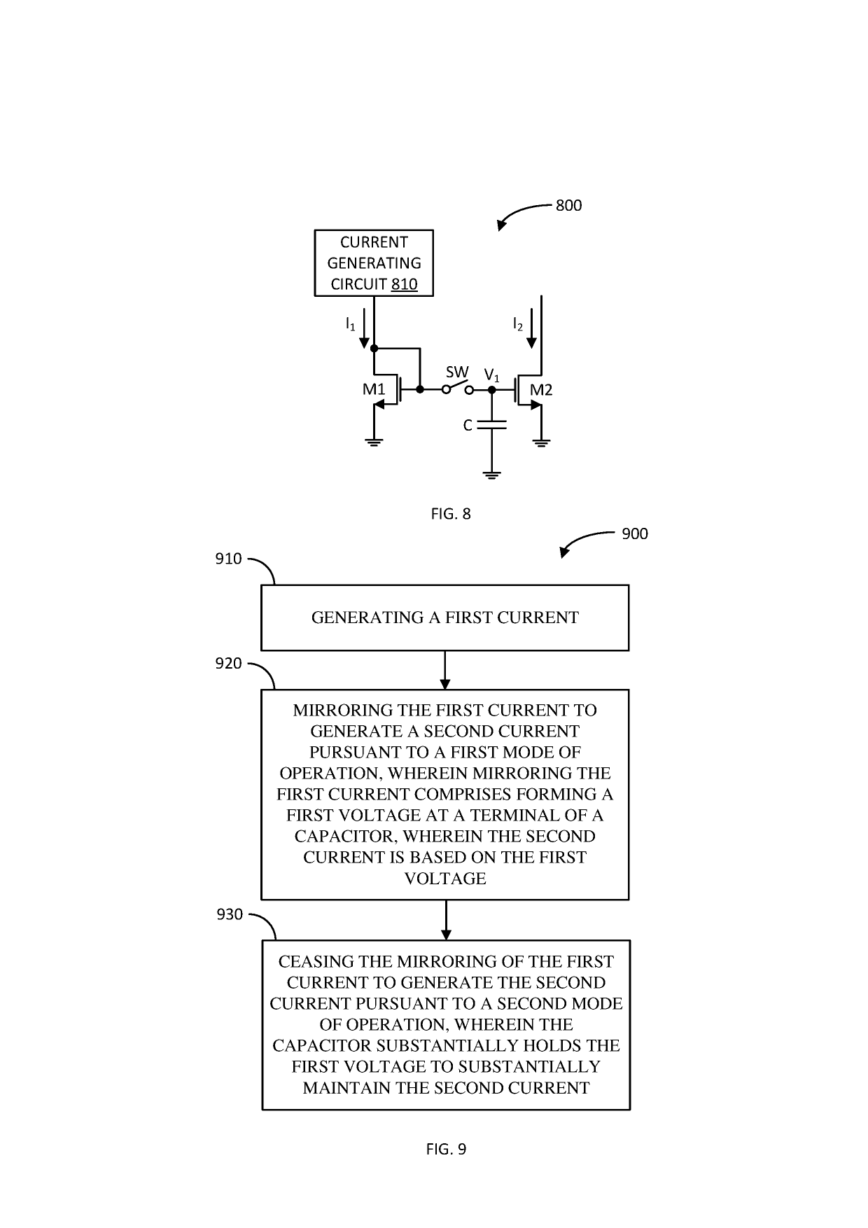

FIG. 8 illustrates a block diagram of an example apparatus (e.g., a current generator, which may be used to generate one or more bias voltages) 800 in accordance with another aspect of the disclosure. The apparatus 800 includes a current generating circuit 810 configured to generate a first current I1. The apparatus 800 further includes a current mirror including a first field effect transistor (FET) M1 and a second FET M2, wherein the first FET M1 is coupled to the current generating circuit 810 such that the first current I1 flows through the first FET M1. In this example, the first and second FETs M1 and M2 are shown to be n-channel field effects transistors NFETs. But, as discussed with reference to bias volage generator 600, it shall be understood that the first and second FETs may be implemented as PFETs.

The apparatus 800 further includes a switching device SW coupled between a gate of the first FET M1 and a gate of the second FET M2. Additionally, the apparatus 800 includes a capacitor C coupled between the gate of the second FET M2 and a voltage rail (e.g., a lower voltage rail, such as ground). However, as discussed with reference to bias volage generator 600, it shall be understood that the voltage rail may be an upper voltage rail Vdd. The current mirror may generate a first voltage V₁ at a first (right) terminal of the switching device SW (e.g., also at the gate of the second FET M2).

The apparatus 800 may further include additional switching devices, such as similarly situated switching devices SW2 and SW3 of bias voltage generator 600 for coupling/decoupling the drain to/from the gate of the first FET M1, and for routing a second voltage to a second (left) terminal of the switching device SW (e.g., also at the gate of the first FET M1) to control current leakage through the switching device SW while it is turned off due to the capacitor C. Additionally, also similar to bias voltage generator 600, the apparatus 800 may include a voltage generating circuit for generating the second voltage, and additional current mirrors for generating bias voltages for one or more current-starved inverters or other components. Furthermore, the current generating circuit 810 may be implemented similar to current generating circuit 610 previously discussed.

FIG. 9 illustrates a flow diagram of an example method 900 of generating a current in accordance with another aspect of the disclosure. The method 900 includes generating a first current (block 910). Examples of means for generating a first current include current generating circuit 610 of bias voltage generator 600 and current generating circuit 810 of apparatus 800.

The method 900 further includes mirroring the first current to generate a second current pursuant to a first mode of operation, wherein mirroring the first current comprises forming a first voltage at a terminal of a capacitor, wherein the second current is based on the first voltage (block 920). Examples of means for mirroring the first current to generate a second current pursuant to a first mode of operation includes current mirror MP3/MP4 of bias voltage generator 600 and current mirror M1/M2 of apparatus 800.

Additionally, the method 900 includes ceasing the mirroring of the first current to generate the second current pursuant to a second mode of operation, wherein the capacitor substantially holds the first voltage to substantially maintain the second current (block 930). An example of means for includes ceasing the mirroring of the first current to generate the second current pursuant to a second mode of operation includes the first switching device SW1 of bias voltage generator 600 or switching device SW of apparatus 800.

The following provides an overview of aspects of the present disclosure:

Aspect 1: An apparatus, comprising: a current generating circuit configured to generate a first current; a first current mirror including a first field effect transistor (FET) and a second FET, wherein the first FET is coupled to the current generating circuit such that the first current flows through the first FET; a first switching device coupled between a gate of the first FET and a gate of the second FET; and a capacitor coupled between a first voltage rail and the gate of the second FET.

Aspect 2: The apparatus of aspect 1, further comprising a control circuit configured to: turn on the first switching device to couple the gate of the first FET to the gate of the second FET pursuant to a first mode of operation, wherein a second current is generated flowing through the second FET based on the first current, and wherein a first voltage is formed at the gate of the second FET; and turn off the first switching device pursuant to a second mode of operation, wherein the capacitor is configured to substantially hold the first voltage at the gate of the second FET such that the second current is maintained flowing through the second FET.

Aspect 3: The apparatus of aspect 2, further comprising a second switching device coupled between the first switching device and the current generating circuit.

Aspect 4: The apparatus of aspect 3, wherein the control circuit is further configured to turn on the second switching device pursuant to the first mode of operation, and turn off the second switching device pursuant to the second mode of operation.

Aspect 5: The apparatus of aspect 4, further comprising: a voltage generating circuit configured to generate a second voltage; and a third switching device coupled between the voltage generating circuit and the gate of the first FET.

Aspect 6: The apparatus of aspect 5, wherein the control circuit is configured to turn off the third switching device pursuant to the first mode of operation, and turn on the third switching device pursuant to the second mode of operation, the second voltage reducing a voltage across the first switching device to reduce current leakage from the capacitor through the first switching device.

Aspect 7: The apparatus of aspect 5 or 6, further comprising a second current mirror configured to generate a third current based on the second current, wherein the voltage generating circuit is configured to generate the second voltage based on the third current.

Aspect 8: The apparatus of any one of aspects 2-7, wherein the second mode of operation is a low power mode of operation.

Aspect 9: The apparatus of any one of aspects 2-8, further comprising: a second current mirror configured to generate a third current based on the second current; and a first bias voltage generating circuit configured to generate a first bias voltage based on the third current.

Aspect 10: The apparatus of aspect 9, further comprising: a third current mirror configured to generate a fourth current based on the second current; and a second bias voltage generating circuit configured to generate a second bias voltage based on the fourth current.

Aspect 11: The apparatus of aspect 10, wherein: the first bias voltage generating circuit comprises a diode-connected p-channel field effect transistor (PFET); and the second bias voltage generating circuit comprises a diode-connected n-channel field effect transistor (NFET).

Aspect 12: The apparatus of claim 11, further comprising a current-starved inverter, comprising: an inverter core including an input configured to receive an input clock signal, and an output configured to output an output clock signal; a first set of switching devices configured to be controlled by a first set of control signals, respectively; a set of PFETs coupled between coupled in series with the first set of switching devices between the first voltage rail and the inverter core, respectively, wherein gates of the set of PFETs are configured to receive the first bias voltage; a set of NFETs including gates configured to receive the second bias voltage; and a second set of switching devices coupled in series with the set of NFETs between the inverter core and a second voltage rail, wherein the second set of switching devices are configured to be controlled by a second set of control signals, respectively, and wherein a delay between the output clock signal and the input clock signal is based on the first and second sets of control signals, the first bias voltage, and the second bias voltage.

Aspect 13: A method, comprising: generating a first current; mirroring the first current to generate a second current pursuant to a first mode of operation, wherein mirroring the first current comprises forming a first voltage at a terminal of a capacitor, wherein the second current is based on the first voltage; and ceasing the mirroring of the first current to generate the second current pursuant to a second mode of operation, wherein the capacitor substantially holds the first voltage to substantially maintain the second current.

Aspect 14: The method of aspect 13, further comprising: turning on a first switching device to effectuate the mirroring of the first current to generate the second current pursuant to the first mode of operation; turning off the first switching device pursuant to the second mode of operation, wherein the first voltage is applied to a first terminal of the first switching device; and providing a second voltage to a second terminal of the first switching device pursuant to the second mode of operation to control leakage current from the capacitor to flow through the first switching device.

Aspect 15: The method of aspect 14, wherein providing the second voltage to the second terminal of the first switching device pursuant to the second mode of operation comprises: mirroring the second current to generate a third current; generating the second voltage based on the third current; and turning on a second switching device to route the second voltage to the second terminal of the first switching device via the second switching device.

Aspect 16: The method of any one of aspects 13-15, further comprising: mirroring the second current to generate a third current; and generating a first bias voltage based on the third current.

Aspect 17: The method of aspect 16, further comprising: mirroring the second current to generate a fourth current; and generating a second bias voltage based on the fourth current.

Aspect 18: The method of aspect 17, further comprising control a delay imparted to an input clock signal to generate an output clock signal based on the first bias voltage and the second bias voltage.

Aspect 19: The method of aspect 18, further comprising phase-frequency locking the output clock signal to a reference clock signal based on the delay.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An apparatus, comprising:
a current generating circuit configured to generate a first current;
a first current mirror including a first field effect transistor (FET) and a second FET, wherein the first FET is coupled to the current generating circuit such that the first current flows through the first FET;
a first switching device coupled between a gate of the first FET and a gate of the second FET; and
a capacitor coupled between a first voltage rail and the gate of the second FET.

2. The apparatus of claim 1, further comprising a control circuit configured to:
turn on the first switching device to couple the gate of the first FET to the gate of the second FET pursuant to a first mode of operation, wherein a second current is generated flowing through the second FET based on the first current, and wherein a first voltage is formed at the gate of the second FET; and
turn off the first switching device pursuant to a second mode of operation, wherein the capacitor is configured to substantially hold the first voltage at the gate of the second FET such that the second current is maintained flowing through the second FET.

3. The apparatus of claim 2, further comprising a second switching device coupled between the first switching device and the current generating circuit.

4. The apparatus of claim 3, wherein the control circuit is further configured to turn on the second switching device pursuant to the first mode of operation, and turn off the second switching device pursuant to the second mode of operation.

5. The apparatus of claim 4, further comprising:
a voltage generating circuit configured to generate a second voltage; and
a third switching device coupled between the voltage generating circuit and the gate of the first FET.

6. The apparatus of claim 5, wherein the control circuit is configured to turn off the third switching device pursuant to the first mode of operation, and turn on the third switching device pursuant to the second mode of operation, the second voltage reducing a voltage across the first switching device to reduce current leakage from the capacitor through the first switching device.

7. The apparatus of claim 5, further comprising a second current mirror configured to generate a third current based on the second current, wherein the voltage generating circuit is configured to generate the second voltage based on the third current.

8. The apparatus of claim 2, wherein the second mode of operation is a low power mode of operation.

9. The apparatus of claim 2, further comprising:
a second current mirror configured to generate a third current based on the second current; and
a first bias voltage generating circuit configured to generate a first bias voltage based on the third current.

10. The apparatus of claim 9, further comprising:
a third current mirror configured to generate a fourth current based on the second current; and
a second bias voltage generating circuit configured to generate a second bias voltage based on the fourth current.

11. The apparatus of claim 10, wherein:
the first bias voltage generating circuit comprises a diode-connected p-channel field effect transistor (PFET); and
the second bias voltage generating circuit comprises a diode-connected n-channel field effect transistor (NFET).

12. The apparatus of claim 11, further comprising a current-starved inverter, comprising:
an inverter core including an input configured to receive an input clock signal, and an output configured to output an output clock signal;
a first set of switching devices configured to be controlled by a first set of control signals, respectively;
a set of PFETs coupled between coupled in series with the first set of switching devices between the first voltage rail and the inverter core, respectively, wherein gates of the set of PFETs are configured to receive the first bias voltage;
a set of NFETs including gates configured to receive the second bias voltage; and
a second set of switching devices coupled in series with the set of NFETs between the inverter core and a second voltage rail, wherein the second set of switching devices are configured to be controlled by a second set of control signals, respectively, and wherein a delay between the output clock signal and the input clock signal is based on the first and second sets of control signals, the first bias voltage, and the second bias voltage.

13. A method, comprising:
generating a first current;
mirroring the first current to generate a second current pursuant to a first mode of operation, wherein mirroring the first current comprises forming a first voltage at a terminal of a capacitor, wherein the second current is based on the first voltage; and
ceasing the mirroring of the first current to generate the second current pursuant to a second mode of operation, wherein the capacitor substantially holds the first voltage to substantially maintain the second current.

14. The method of claim 13, further comprising:
turning on a first switching device to effectuate the mirroring of the first current to generate the second current pursuant to the first mode of operation;
turning off the first switching device pursuant to the second mode of operation, wherein the first voltage is applied to a first terminal of the first switching device; and
providing a second voltage to a second terminal of the first switching device pursuant to the second mode of operation to control leakage current from the capacitor to flow through the first switching device.

15. The method of claim 14, wherein providing the second voltage to the second terminal of the first switching device pursuant to the second mode of operation comprises:
mirroring the second current to generate a third current;
generating the second voltage based on the third current; and
turning on a second switching device to route the second voltage to the second terminal of the first switching device via the second switching device.

16. The method of claim 13, further comprising:
mirroring the second current to generate a third current; and
generating a first bias voltage based on the third current.

17. The method of claim 16, further comprising:
mirroring the second current to generate a fourth current; and
generating a second bias voltage based on the fourth current.

18. The method of claim 17, further comprising control a delay imparted to an input clock signal to generate an output clock signal based on the first bias voltage and the second bias voltage.

19. The method of claim 18, further comprising phase-frequency locking the output clock signal to a reference clock signal based on the delay.
